(19) United States
(12) Patent Application Publication
(10) Pub. No.: US 2019/0212401 A1
(43) Pub. Date: Jul. 11, 2019

(54) WHOLE BODY NON-CONTACT ELECTRICAL STIMULATION DEVICE WITH VARIABLE PARAMETERS

(71) Applicant: Neva Electromagnetics, LLC, Yarmouth Port, MA (US)

(72) Inventors: Sergey Makarov, Holden, MA (US); Gregory M. Noetscher, Shrewsbury, MA (US); Viktor S. Makarov, Holden, MA (US); Zhi-De Deng, Bethesda, MD (US); Gene Bogdanov, Manchester, CT (US); William L. Appleyard, Hudson, MA (US)

(21) Appl. No.: 16/212,595

(22) Filed: Dec. 6, 2018

Related U.S. Application Data
(63) Continuation-in-part of application No. 15/868,038, filed on Jan. 11, 2018.

(51) Int. Cl. G01R 33/34

(52) U.S. Cl. CPC G01R 33/34076

(57) ABSTRACT

The present invention relates to an electromagnetic device for non-contact injection of strong modulated (0-1000 Hz) electric fields with intensity of 1-2 volts per centimeter into a whole human body at the frequency band 10-500 kHz. The device of the present invention is a low-pass birdcage coil resonator with a very large number of rungs, with two inductively coupled loop feeds, and with a high quality factor of 300.

### CROSS-REFERENCE TO RELATED APPLICATIONS

This application claims benefit of U.S. patent application Ser. No. 15/868,038, filed Jan. 11, 2018. The subject matter if that application is hereby included in its entirety.

### FIELD OF THE INVENTION

The present invention relates to an electromagnetic device for non-contact injection of strong modulated electric fields into a whole human body at the frequency band 10-500 kHz.

### BACKGROUND OF THE INVENTION

The conventional Mill (Magnetic Resonance Imaging) RF (Radio Frequency) coil or a birdcage resonator known from Mill instrumentation cannot be used in the frequency band 10-500 kHz since its quality factor [symbol] , the “gain” of the resonator, becomes very low (less than one). As a result, the induced electric field in a body will be low too. To achieve high levels of the stimulation electric field, a birdcage coil resonator operating at a much lower carrier frequency of around 10-500 kHz is required. The carrier may then amplitude-modulated by any required base frequency in the range of 0-1000 Hz or by constructing pulsed excitation with a center frequency not to exceed 1000 Hz.

Accordingly, a resonator with a high field, 1-2 volts per centimeter, that operates at much lower than frequencies is required. The birdcage resonator of the present invention uses a very large number of rungs in excess of 100 while the conventional MM resonator uses 8-16 rungs. It also uses inductively coupled feeds to ensure no direct current from the AC power outlet to the coil. These two factors allow achievement of a very high quality factor of 300 and high-fields of 1-2 volts per centimeter. The device of the present invention does not require the use of any magnetic materials and is lightweight and portable. At the same time, significant electric field levels within the body due to the resonance effect may be achieved. Although the resonant or carrier frequency of the device is fixed, the electric field within the resonator volume could be amplitude modulated from approximately 0.4 Hz to 150 Hz. Such a device may be used to modulate the field level with any signal including electroencephalographic signals from the brain to establish closed-loop feedback for the entire peripheral and/or nervous system. Other potential applications include treatment of chronic pain, oncological and psychiatric applications.

### SUMMARY OF THE INVENTION

The present invention provides a resonant non-contact device, wherein the device creates strong variable electric fields in the human body in the frequency band 10-500 kHz. The device of the present invention comprises a modified birdcage coil or birdcage resonator. The generally cylindrical birdcage coil is further comprised of a pair of end rings, a plurality of generally parallel rungs or column elements bridging the end rings, and a plurality of matching capacitors to control the coil's resonant frequency. The coil is fed with at least two lumped ports in quadrature or using inductive coupling with at least two loops in quadrature.

In a preferred embodiment, the end rings are disposed in parallel planes along the coil axis and the parallel rungs interconnect the end rings. The end rings may be detachable to the parallel rungs. The plurality of parallel rungs, preferably 50-200, more preferably 100-160, are spaced generally equally about the end rings. In a preferred embodiment, the parallel rungs are comprised of a conductive material, preferably copper, and preferably thin-walled copper tubing. In a further embodiment, the thickness of the wall of the rungs is preferably 0.1-2 mm to avoid excessive eddy current losses.

In a further embodiment, each parallel rung is comprised of two rung portions with a capacitor located at the attachment point of the two rung portions. Variable resonance of frequency from 10 to 500 kHz is achieved through the use of replaceable capacitor banks bridging each of the coil rungs. In order to realize a desired resonance frequency, the appropriate, pre-constructed capacitor banks are inserted into the device. These capacitor banks may be easily modified to reach a particular desired resonance. The capacitors are located distal to the end rings and, preferably, equidistant to each end ring. The capacitors are, preferably matching and in the nanofarad range used to tune the resonator to the desired frequency. In a preferred embodiment the capacitors are sized to operate at currents up to at least 15 A RMS per rung and voltages up to at east 240 V RMS for a maximum power of 3 kW across the capacitor. In a preferred embodiment, the coil resonates at approximately 100 kHz or at approximately 145 kHz depending on the bridging capacitor values.

In a preferred embodiment, two inductively coupled loop feeds are disposed outside the parallel rungs proximally to the coil center. Each loop feed is shifted 90 degrees about the coil axis. In a further embodiment, the coil of the present invention is driven through two inductively coupled feeds in quadrature by an amplifier. In a preferred embodiment, the amplifier is a high efficiency, low-cost, single-frequency power amplifier comprising a Class-S modulator followed by two class-D output stages in quadrature exciting the two resonant modes. In a further embodiment, the amplifier has at least two outputs for each resonant mode and generates a harmonic power RF signal at a fixed carrier frequency at each output. The amplifier may be tuned to operate at any carrier frequency from 20 kHz to 400 kHz in the LF band. In a further embodiment, the power amplifier includes amplitude modulation in the frequency band 0.4 to 150 Hz, The amplifier is preferably connected to the inductive coupling loops of the coil with two isolated cables of variable length to enable convenient operation.

In a preferred embodiment, the amplifier operation, including, but not limited to power levels, variable modulation, and RF frequency tuning, is automated, preferably via microcontroller, and monitors output power and load impedance. In a further embodiment, the RF tuning is semiautomated subject-specific. The degree of tuning required to enable subject-specific tuning is obtained through real-time monitoring of the Smith chart and reflection coefficient of the coil during all (loaded or unloaded) conditions. Changes in resonance due to patient body composition and/or position are detected and the adjustable components of the system are attuned to optimize resonance. This ensures maximum resonant power is achieved. This information allows the amplifier to adjust the carrier frequency in a narrow band such that the output power remains on target. In a further embodiment, the amplifier uses air cooling and is powered by Direct Current power supply.

In a further embodiment, the coil is framed. The framed coil may be placed horizontally and augmented with a horizontal bed to enable a subject to lay down. The frame and coil are preferably portable.

### BRIEF DESCRIPTION OF THE DRAWINGS

FIG. 1a is a schematic representation of a birdcage resonator of the present invention.

FIG. 1b is a schematic representation of a birdcage coil of the present invention.

FIG. 2 is a schematic of the power amplifier.

FIG. 3a is a schematic of the matching and tuning network of the amplifier

FIG. 3b is a schematic of the two-coupling loop feed.

### DETAILED DESCRIPTION OF THE INVENTION

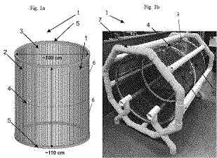

FIG. 1a shows a birdcage resonator 1 of the present invention. The resonator comprises end rings 5, capacitors 4, parallel rungs 3, and inductive loop feeds 2. The end rings 5 are disposed along parallel planes and are interconnected by the parallel rungs 3. Each parallel rung 3 is comprised of at least two leg portions 6. Capacitors 4 connect the rung portions 6 to form a parallel rung 3. Inductively coupled loop feeds 2 are placed parallel to rungs 3.

FIG. 1b shows the birdcage resonator 1 supported by plastic frame 7. FIG. 1b further shows that each parallel rung 3 is comprised of at least two leg portions 6.

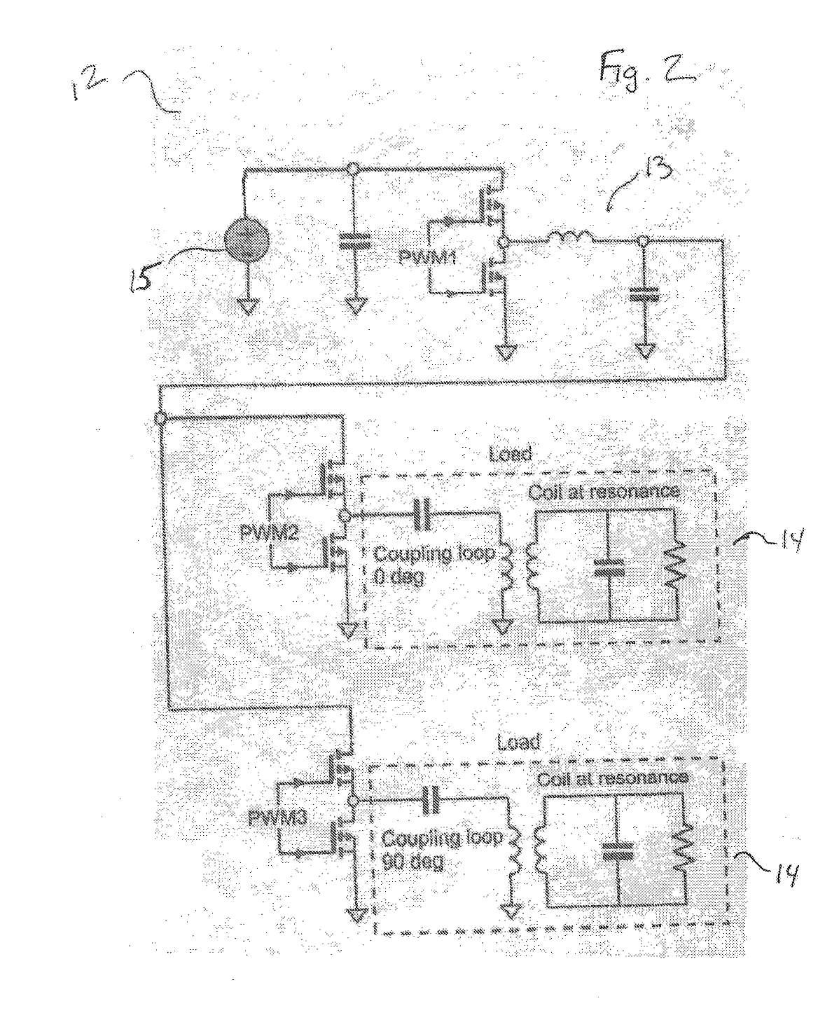

FIG. 2 shows schematic for the power amplifier 12. The upper block 13, is a Class-S modulator, which is followed by two class-D output stages 14 in quadrature. The amplifier is powered by a Direct Current power supply 15.

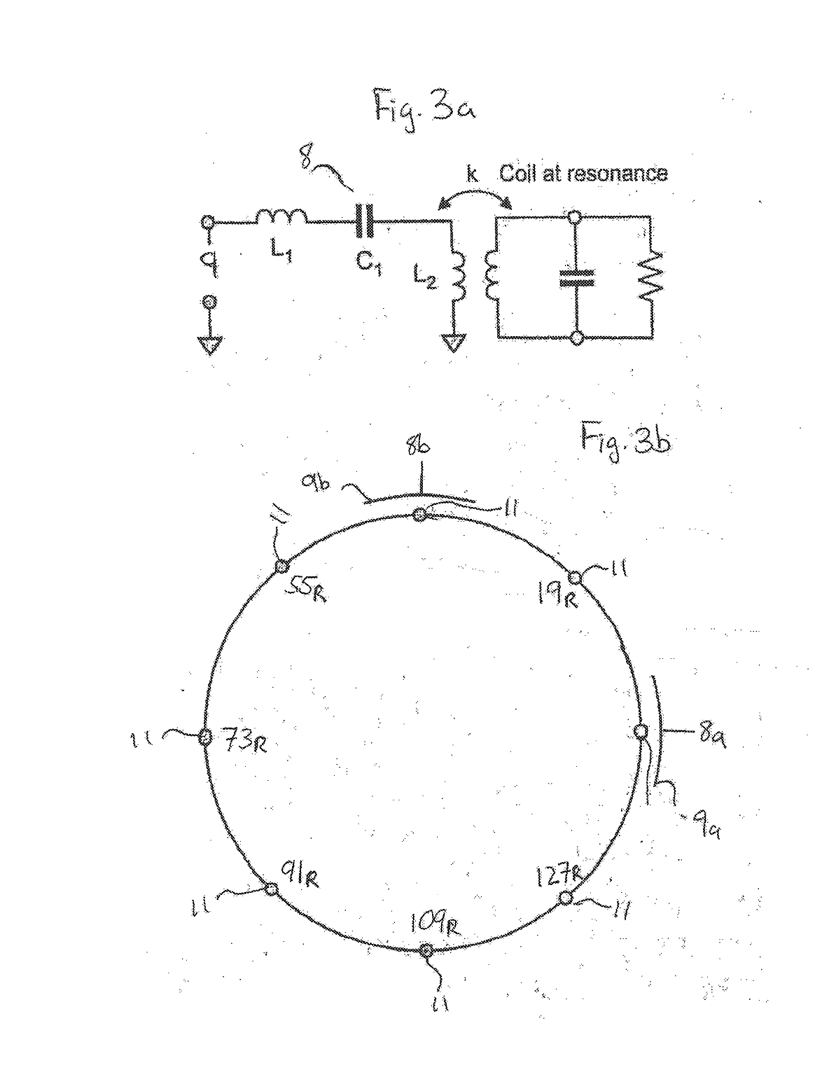

FIG. 3a shows the matching network 8 for a coil port 9. The port matching network consists 8 of a series capacitance C₁, series inductance L₁, and fixed inductance L₂ of the coupling loop (not shown). Two ports 9a and 9b with identical matching networks 8a and 8b are located 90° apart around a coil structure 10, wherein the coil structure 10 is comprised of 144 rung capacitors 11, as shown in numbered locations 1R, 19R, 37R, 55R, 73R, 91R, 109R and 127R (each individual rung capacitor is not shown) in FIG. 3b. The primary adjustable components of the semiautomatic subject-specific RF tuning are the series capacitance C₁ and the coil rung capacitors 11 at the numbered locations in FIG. 3b.

We claim:

1. A high-quality factor large-size radiofrequency resonator at 10-500 kHz comprising:
a pair of end rings;
a plurality of rungs, wherein the plurality of rungs bridge the end rings and the plurality of rungs are generally parallel and spaced evenly about the end rings;
a pair of inductive loop feeds wherein the inductive loop feeds are placed parallel to the plurality of rungs.

2. The resonator of claim 1 wherein the plurality of rungs and the pair of end rings are comprised of thin-walled copper.

3. The resonator of claim 2 wherein the electric field in a human body within the resonator reaches and exceeds one volt per centimeter when driven by a 3 kilowatt power source.

4. The resonator of claim 3 wherein the electric field in a human body within the resonator may be modulated by any low frequency from 0 to 1000 Hz.
